(19) United States
(12) Patent Application Publication
(10) Pub. No.: US 2017/0287126 A1
(43) Pub. Date: Oct. 5, 2017

(54) Method of evaluating aligned patterns in directed self-assembly and using in feedback control scheme

(71) Applicant: Tokyo Electron Limited, Tokyo (JP)

(72) Inventors: Michael Carcasi, Austin, TX (US); Mark Somervell, Austin, TX (US)

(73) Assignee: Tokyo Electron Limited, Tokyo (JP)

(21) Appl. No.: 15/281,692

(22) Filed: Sep. 30, 2016

Related U.S. Application Data
(60) Provisional application No. 62/316,480, filed on Mar. 31, 2016.

(51) Int. Cl. G06T 7/00; H01L 21/66

(52) U.S. Cl. CPC G06T 7/0004; H01L 22/12; G06T 2207/30148

(57) ABSTRACT

Embodiments of methods and systems for inspecting a pattern are described. The method may include providing a substrate with a pattern formed thereupon, the pattern comprising aligned features. Additionally, the method may include acquiring one of more aerial images of the pattern, each image comprising a 2-dimensional (2D) array of pixels, each pixel having an intensity. Further, the method may include transforming at least one of the one or more aerial images into spatial frequency domain to form a transform. The method may also include selecting an alignment metric defined in the spatial frequency domain, the alignment metric being correlated to a level of alignment of the pattern. Additionally, the method may include calculating the alignment metric to evaluate the level of alignment of the pattern.

### CROSS-REFERENCE TO RELATED APPLICATIONS

This application claims priority to U.S. Provisional Patent Application No. 62/316,480, entitled “METHOD OF EVALUATING ALIGNED PATTERNS IN DIRECTED SELF-ASSEMBLY AND USING IN FEEDBACK,” filed on Mar. 31, 2016, the entirety of which is incorporated herein by reference.

### BACKGROUND OF THE INVENTION

Field of Invention

The present invention relates to systems and methods for substrate processing, and more particularly to a method and system for evaluating aligned patterns in Directed Self-Assembly (DSA) and using the alignment data in a feedback control scheme.

Description of Related Art

The need to remain competitive in cost and performance in the production of semiconductor devices has caused a continuous increase in device density of integrated circuits. Higher integration and miniaturization in a semiconductor integrated circuit, requires an associated miniaturization of a circuit pattern formed on a semiconductor wafer.

Photolithography is a standard technique used to manufacture semiconductor integrated circuitry by transferring geometric shapes and patterns on a mask to the surface of a semiconductor wafer. Current state-of-the-art photolithography tools only allow feature sizes down to about 25 nm. Accordingly, new methods are needed to provide smaller features.

Directed Self Assembly (DSA) of integrated circuits has been used to further reduce feature sizes. One type of DSA includes self-assembly of block copolymers (BCPs), which has been considered a potential tool for improving the resolution to better values than those obtainable by prior art lithography methods alone. Block copolymers are useful compounds in nanofabrication, because they may undergo an order-disorder transition on cooling below a certain temperature (order-disorder transition temperature TOD), resulting in phase separation of copolymer blocks of different chemical nature to form ordered, chemically distinct domains with dimensions of tens of nanometers or even less than 10 nm. The size and shape of the domains may be controlled by manipulating the molecular weight and composition of the different block types of the copolymer. The interfaces between the domains may have widths of the order of 1 nm to 5 nm and may be manipulated by modification of the chemical compositions of the blocks of the copolymer.

A block copolymer may form many different phases upon self-assembly, dependent upon the volume fractions of the blocks, degree of polymerization within each block type (i.e., number of monomers of each respective type within each respective block), the optional use of a solvent and surface interactions. When applied in a thin film, the geometric confinement may present additional boundary conditions, which may limit the number of phases. In general, spherical (e.g., cubic), cylindrical (e.g., tetragonal or hexagonal) and lamellar phases (i.e., self-assembled phases with cubic, hexagonal or lamellar space-filling symmetry) are practically observed in thin films of self-assembled block copolymers, and the phase type observed may depend upon the relative volume fractions of the different polymer blocks. The self-assembled polymer phases may orient with symmetry axes parallel or perpendicular to the substrate and lamellar and cylindrical phases are interesting for lithography applications, because they may form line and spacer patterns and contact hole arrays, respectively, and may provide good contrast when one of the domain types is subsequently etched.

Two methods used to guide DSA of a block copolymer onto a surface are grapho-epitaxy and chemical pre-patterning, also called chemi-epitaxy. In the grapho-epitaxy method, self-organization of a block copolymer is guided by topological pre-patterning of the substrate. A self-aligned block copolymer can form a parallel linear pattern with adjacent lines of the different polymer block domains in the trenches defined by the patterned substrate. For example, if the block copolymer is a di-block copolymer with A and B blocks within the polymer chain, where A is hydrophilic and B is hydrophobic in nature, the A blocks may assemble into domains formed adjacent to a side-wall of a trench if the side-wall is also hydrophilic in nature. Resolution may be improved over the resolution of the patterned substrate by the block copolymer pattern subdividing the spacing of a pre-pattern on the substrate.

Accordingly, to achieve the advantages provided by grapho-epitaxy and chemi-epitaxy of block copolymers, new lithographic patterning and DSA techniques are required, including the ability to integrate such materials in patterning workflows. One example of a block copolymer is polystyrene-b-poly(methyl methacrylate) (PMMA). However, when removing the PMMA portion from the polystyrene-b-poly(methyl methacrylate) (PS-b-PMMA) layer to leave behind a polystyrene (PS) pattern, conventional etching techniques have suffered. Due to the organic nature of both materials, and their similarities, developing an etch chemistry with suitable etch selectivity has been challenging. Furthermore, conventional etch processes produce pattern defectivity, such as line edge roughness/line width roughness (LER/LWR), that are unacceptable as per the semiconductor device performance requirements. In extreme cases, the defectivity of the PS can be catastrophic due to pattern collapse. For these reasons, defect detection methods are needed.

A further challenge lies in detecting defects which are sub-surface and in the bulk of phase separated BCP films. Commonly used metrology methods like Critical Dimension Scanning Electron Microscope (CDSEM) and optical scattering methods cannot detect such defects because of low selectivity etching processes, which tend to mitigate prior to detection.

### SUMMARY OF THE INVENTION

Embodiments of methods and systems for inspecting a pattern are described. The method may include providing a substrate with a pattern formed thereupon, the pattern comprising aligned features. Additionally, the method may include acquiring one of more aerial images of the pattern, each image comprising a 2-dimensional (2D) array of pixels, each pixel having an intensity. Further, the method may include transforming at least one of the one or more aerial images into spatial frequency domain to form a transform. The method may also include selecting an alignment metric defined in the spatial frequency domain, the alignment metric being correlated to a level of alignment of the pattern. Additionally, the method may include calculating the alignment metric to evaluate the level of alignment of the pattern.

### BRIEF DESCRIPTION OF THE DRAWINGS

The accompanying drawings, which are incorporated in and constitute a part of this specification, illustrate embodiments of the invention and, together with the general description of the invention given above, and the detailed description given below, serve to describe the invention.

FIG. 1A depicts a schematic of a semiconductor device during one stage of DSA processing.

FIG. 1B depicts a schematic of a semiconductor device during one stage of DSA processing.

FIG. 1C depicts a schematic of a semiconductor device during one stage of DSA processing.

FIG. 2A depicts an embodiment of a semiconductor device manufactured by a DSA process having a dislocation pair defect.

FIG. 2B is a cross-section view of an embodiment of a semiconductor device having a dislocation pair defect.

FIG. 2C depicts an embodiment of a semiconductor device manufactured by a DSA process having a disclination defect.

FIG. 2D is a cross-section view of an embodiment of a semiconductor device having a disclination defect.

FIG. 2E depicts an embodiment of a semiconductor device manufactured by a DSA process having a buried defect.

FIG. 2F is a cross-section view of an embodiment of a semiconductor device having a buried defect.

FIG. 3 illustrates an embodiment of an image of a top view of one embodiment of a semiconductor device manufactured by a DSA process.

FIG. 4 illustrates an embodiment of an image of a top view of one embodiment of a semiconductor device manufactured by a DSA process.

FIG. 5A illustrates a one-dimensional power spectrum measurement of each row of the image of FIG. 3.

FIG. 5B illustrates a row average of the one-dimensional power spectrum measurement of the image of FIG. 3.

FIG. 6A illustrates a one dimensional power spectrum measurement of each row of the image of FIG. 4.

FIG. 6B illustrates a row average of the one-dimensional power spectrum measurement of the image of FIG. 4.

FIG. 7A illustrates a two-dimensional power spectrum measurement of each row of the image of FIG. 3.

FIG. 7B illustrates a rotational average of the two-dimensional power spectrum measurement of the image of FIG. 3.

FIG. 8A illustrates a two-dimensional power spectrum measurement of each row of the image of FIG. 4.

FIG. 8B illustrates a rotational average of the two-dimensional power spectrum measurement of the image of FIG. 4.

FIG. 9 illustrates an embodiment of a set of images of semiconductor devices manufactured by a DSA process ordered by visual assessment of alignment.

FIG. 10A illustrates a two-dimensional power spectrum first order peak height measurement for each of the images of FIG. 9.

FIG. 10B illustrates a one-dimensional power spectrum sum of second order peak height measurement for each of the images of FIG. 9.

FIG. 10C illustrates a one-dimensional power spectrum sum of first order peak height measurement for each of the images of FIG. 9.

FIG. 11 is a schematic flowchart diagram illustrating one embodiment of a method for evaluating aligned patterns in DSA semiconductor devices.

FIG. 12 is a schematic flowchart diagram illustrating one embodiment of a method for evaluating aligned patterns in DSA semiconductor devices.

FIG. 13 is a schematic block diagram illustrating one embodiment of a processing device specially configured for evaluating aligned patterns in DSA semiconductor devices.

### DETAILED DESCRIPTION OF EMBODIMENTS OF THE INVENTION

Methods and systems for patterning sidewall shapes are presented. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention.

Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale. In referencing the figures, like numerals refer to like parts throughout.

Reference throughout this specification to “one embodiment” or “an embodiment” or variation thereof means that a particular feature, structure, material, or characteristic described in connection with the embodiment is included in at least one embodiment of the invention, but does not denote that they are present in every embodiment. Thus, the appearances of the phrases such as “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Additionally, it is to be understood that “a” or “an” may mean “one or more” unless explicitly stated otherwise.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

As used herein, the term “substrate” means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOT”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

As used herein, the term “radiation sensitive material” means and includes photosensitive materials such as photoresists.

As used herein, the term “polymer block” means and includes a grouping of multiple monomer units of a single type (i.e., a homopolymer block) or multiple types (i.e., a copolymer block) of constitutional units into a continuous polymer chain of some length that forms part of a larger polymer of an even greater length and exhibits a _{χ}N value, with other polymer blocks of unlike monomer types, that is sufficient for phase separation to occur. _{χ} is the Flory-Huggins interaction parameter and N is the total degree of polymerization for the block copolymer. According to embodiments of the present invention, the _{χ}N value of one polymer block with at least one other polymer block in the larger copolymer may be equal to or greater than about 10.5.

As used herein, the term “block copolymer” means and includes a polymer composed of chains where each chain contains two or more polymer blocks as defined above and at least two of the blocks are of sufficient segregation strength (e.g., _{χ}N>10.5) for those blocks to phase separate. A wide variety of block polymers are contemplated herein including di-block copolymers (i.e., polymers including two polymer blocks (AB)), tri-block copolymers (i.e., polymers including three polymer blocks (ABA or ABC)), multi-block copolymers (i.e., polymers including more than three polymer blocks (ABCD, etc.)), and combinations thereof.

The terms “microphase segregation” and “microphase separation,” as used herein mean and include the properties by which homogeneous blocks of a block copolymer aggregate mutually, and heterogeneous blocks separate into distinct domains. In the bulk, block copolymers can self-assemble into ordered morphologies, having spherical, cylindrical, and lamellar, bicontinuous gyroid, or miktoarm star micro domains, where the molecular weight of the block copolymer dictates the sizes of the micro domains formed.

The domain size or pitch period (Lo) of the self-assembled block copolymer morphology may be used as a basis for designing critical dimensions of the patterned structure. Similarly, the structure period (Ls), which is the dimension of the feature remaining after selectively etching away one of the polymer blocks of the block copolymer, may be used as a basis for designing critical dimensions of the patterned structure. The lengths of each of the polymer blocks making up the block copolymer may be an intrinsic limit to the sizes of domains formed by the polymer blocks of those block copolymers. For example, each of the polymer blocks may be chosen with a length that facilitates self-assembly into a desired pattern of domains, and shorter and/or longer copolymers may not self-assemble as desired.

The term “annealing” or “anneal” as used herein means and includes treatment of the block copolymer so as to enable sufficient microphase segregation between the two or more different polymeric block components of the block copolymer to form an ordered pattern defined by repeating structural units formed from the polymer blocks. Annealing of the block copolymer in the present invention may be achieved by various methods known in the art, including, but not limited to: thermal annealing (either in a vacuum or in an inert atmosphere, such as nitrogen or argon), solvent vapor-assisted annealing (either at or above room temperature), supercritical fluid-assisted annealing, or absorption-based annealing (e.g., optical baking). As a specific example, thermal annealing of the block copolymer may be conducted by exposing the block copolymer to an elevated temperature that is above the glass transition temperature (Tg), but below the degradation temperature (Td) of the block copolymer, as described in greater detail hereinafter. Other conventional annealing methods not described herein may also be utilized.

The ability of block copolymers to self-organize may be used to form mask patterns. Block copolymers are formed of two or more chemically distinct blocks. For example, each block may be formed of a different monomer. The blocks are immiscible or thermodynamically incompatible, e.g., one block may be polar and the other may be non-polar. Due to thermodynamic effects, the copolymers will self-organize in solution to minimize the energy of the system as a whole; typically, this causes the copolymers to move relative to one another, e.g., so that identical blocks aggregate together, thereby forming alternating regions containing each block type or species. For example, if the copolymers are formed of polar (e.g., organometallic containing polymers) and non-polar blocks (e.g., hydrocarbon polymers), the blocks will segregate so that non-polar blocks aggregate with other non-polar blocks and polar blocks aggregate with other polar blocks. It will be appreciated that the block copolymers may be described as a self-assembling material since the blocks can move to form a pattern without active application of an external force to direct the movement of particular individual molecules, although heat may be applied to increase the rate of movement of the population of molecules as a whole.

In addition to interactions between the polymer block species, the self-assembly of block copolymers can be influenced by topographical features, such as steps or guides extending perpendicularly from the horizontal surface on which the block copolymers are deposited. For example, a di-block copolymer, a copolymer formed of two different polymer block species, may form alternating domains, or regions, which are each formed of a substantially different polymer block species. When self-assembly of polymer block species occurs in the area between the perpendicular walls of a step or guides, the steps or guides may interact with the polymer blocks such that, e.g., each of the alternating regions formed by the blocks is made to form a regularly spaced apart pattern with features oriented generally parallel to the walls and the horizontal surface.

Such self-assembly can be useful in forming masks for patterning features during semiconductor fabrication processes. For example, one of the alternating domains may be removed, thereby leaving the material forming the other region to function as a mask. The mask may be used to pattern features such as electrical devices in an underlying semiconductor substrate. Methods for forming a block copolymer mask are disclosed in U.S. Pat. No. 7,579,278; U.S. Pat. No. 7,723,009, and to U.S. application Ser. No. 13/830,859, CHEM1-EPITAXY IN DIRECTED SELF-ASSEMBLY APPLICATIONS USING PHOTO-DECOMPOSABLE AGENTS, by Somervell, et al., filed on Mar. 14, 2013, the entire disclosure of each of which is incorporated by reference herein.

In material processing methodologies, pattern etching can comprise the application of a thin layer of radiation-sensitive material, such as photo-resist, to an upper surface of a substrate, followed by patterning of the thin layer of material using lithographic techniques. In DSA patterning, the initial pattern is formed by the phase-separation of two or more phases present in a DSA layer, the selective removal of at least one phase using dry pattern etching, and the retention of at least one remaining phase, thereby providing a pattern for subsequent dry pattern etching. During dry pattern etching, a plasma etching process can be utilized, wherein plasma is formed from a process gas by coupling electro-magnetic (EM) energy, such as radio frequency (RF) power, to the process gas in order to heat electrons and cause subsequent ionization and dissociation of the atomic and/or molecular constituents of the process gas. Using a series of dry etching processes, the initial pattern may be formed in the DSA layer, followed by transfer of the pattern to the underlying layers within a film stack, including the one or more material layers that are desired for the end product, e.g., electronic device. To do so, the selective removal of one material relative to other material(s) is necessary. And, among other things, during the pattern transfer process, profile control for the pattern extended into underlying layers is of critical importance.

The described embodiments include performing a Capacitive Coupled Plasma (CCP)-based curing process for selective treatment, or hardening, of PS regions in PS-b-PMMA block copolymer DSA films prior to dry etch development of PMMA regions. In various embodiments, the curing chemistry can be Ar/H2, HBr, N2/H2, etc., which has the capability of generating Vacuum Ultraviolet (VUV) photon flux for polymer curing. The curing effect may enhance the etch resistance of PS regions, thereby freezing the bulk defects during plasma PMMA removal. The defects can then be measured by commonly used metrology techniques like CDSEM and quantized.

One advantage of the described methods is enhanced visibility and detection of the bulk defects, which otherwise cannot be measured. Such embodiments enable defect metrology of DSA patterning, thereby making DSA devices manufacturable, eliminating the requisite number of processing steps, and semiconductor processing, as well as reducing manufacturing time and cost. Additionally, such embodiments can be useful for quick evaluation of various BCP film materials, thereby reducing learning cycle times.

Introduction of a plasma curing step prior to removing PMMA from PS-PMMA DSA mask films may enhance etch resistance of the PS regions in the bulk of the film, thereby making bulk defects clearly visible in the form of bridging, line flops and sidewall roughness during dry plasma removal of PMMA. Without the plasma curing step prior to plasma-etch removal of PMMA from DSA films, on the other hand, the remaining PS mask margin is limited only to pattern transfer into the underlying Anti-Reflective Coating (ARC) layer. Therefore, a high selectivity process for DSA film development can be used as an alternative to a Self-Aligned Doubled Patterning (SADP) process, thereby eliminating several processing steps and making manufacturing much more cost effective for advanced technology devices. For example, such embodiments may provide additional process flexibility for patterning at sub 32 nm pitches.

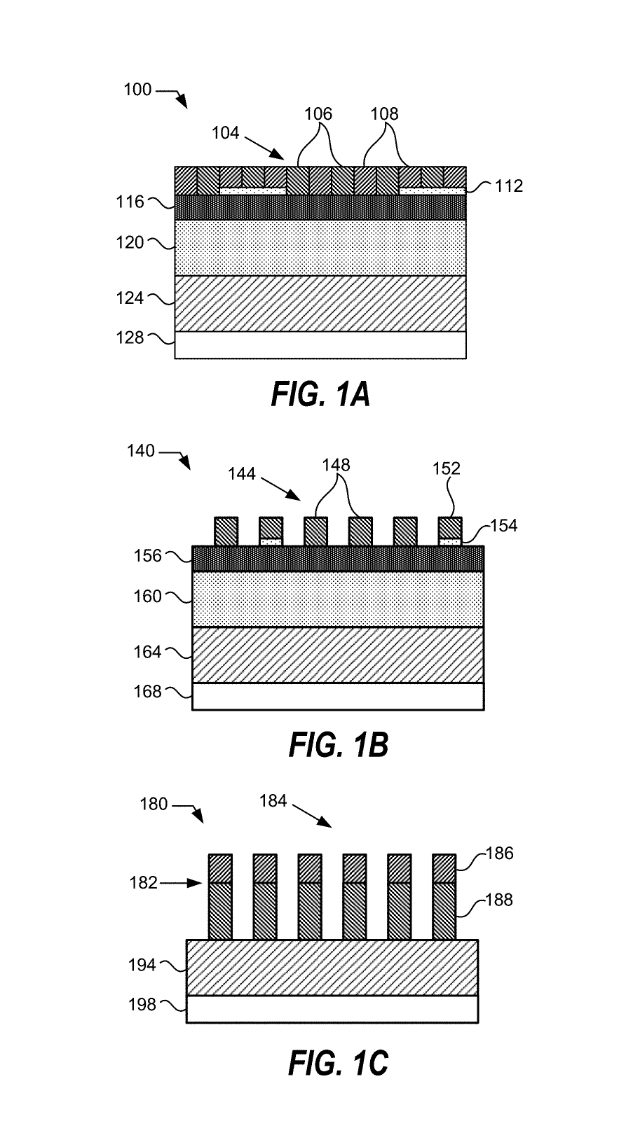

Referring now to the drawings, wherein like reference numerals designate identical or corresponding parts throughout the several views, FIG. 1A depicts a schematic 100 of an input substrate 104 with a DSA pattern in a DSA patterning process. The top layer 112 includes a BCP comprising a first block copolymer 106 and a second copolymer 108. The first block copolymer 106 can be PMMA and a second copolymer 108 can be polystyrene. Connecting two adjacent second block copolymer 108 is a neutral layer 112. The next layers of the underlying layer include silicon anti-reflective coating (SiARC) layer 116, spin-on carbon hard mask (CHM) layer 120, an oxide layer 124, and a silicon layer 128. The technology for fabricating the DSA pattern and the layers of the underlying layer is discussed above and is known to people in the art.

FIG. 1B depicts a schematic 140 of a substrate 144 after the second copolymer and portions of neutral layer are etched with the DSA patterning process, leaving the first copolymer 148 and portions of the neutral layer 154. The next layers include a SiARC layer 156, a spin-on CHM layer 160, an oxide layer 164, and a silicon layer 168.

FIG. 1C depicts a schematic 180 of a substrate 184 after the SiARC and CHM etch process in a DSA patterning process. The structure pattern 182 comprises a SiARC portion 186 and a CHM portion 188. The next layers include an oxide layer 194 and a silicon layer 198.

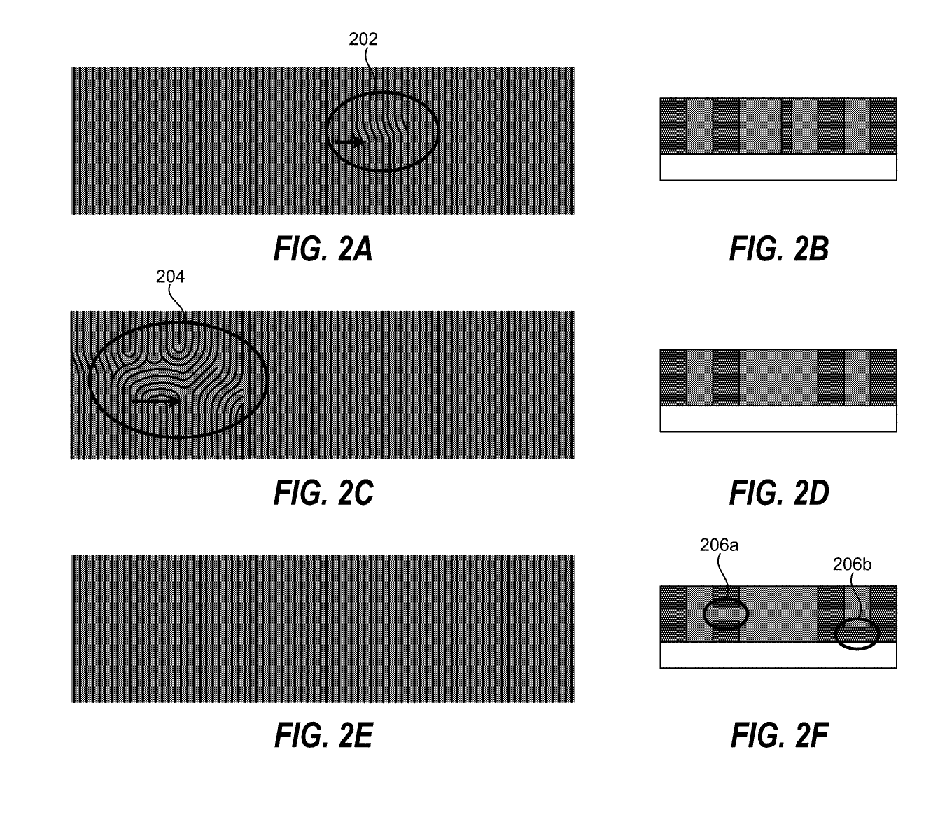

Unfortunately, semiconductor devices manufactured according to DSA processes, such as those described in FIGS. 1A-1C may include defects, such as those depicted in FIGS. 2A-2F. FIG. 2A depicts an embodiment of a semiconductor device manufactured by a DSA process having a dislocation pair defect 202. FIG. 2B illustrates a cross-section view of a dislocation pair defect 202. FIG. 2C depicts an embodiment of a semiconductor device manufactured by a DSA process having a disclination defect 204, and FIG. 2D is a cross-section view of the disclination defect 204. FIG. 2E depicts an embodiment of a semiconductor device manufactured by a DSA process having a buried defect (not visible), and FIG. 2F illustrates a cross-section view diagram illustrating a buried defect 206a, 206b.

One uncertainty relating to DSA processes includes defect density levels, and defect types for line/space process flows. The traditional topological defects such as dislocation and disclination defects shown in FIGS. 2A-2D are relatively easy to identify, because they tend to cause a ripple effect, enlarging their actual footprint, and thus making them visible to both electron and optical inspection tools. However, buried defects are still difficult to detect using traditional metrology techniques. Examples of buried defects include the formation of either PS or PMMA bridges as shown in FIG. 2F.

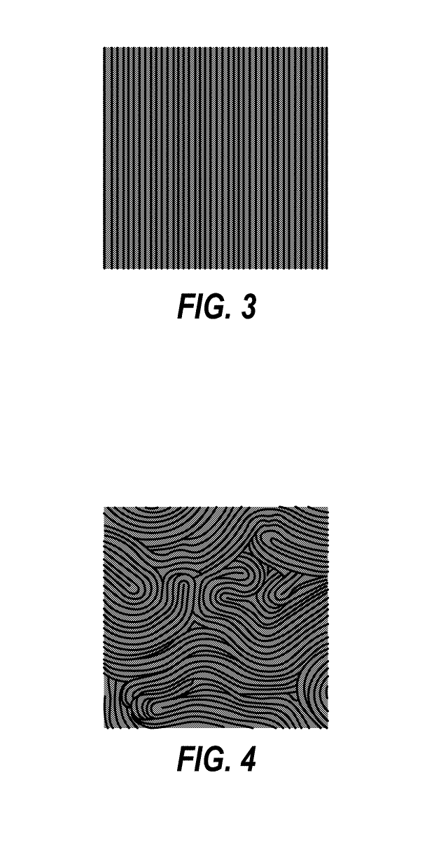

FIG. 3 illustrates an embodiment of an image of a top view of one embodiment of a semiconductor device manufactured by a DSA process. The embodiment of FIG. 3 is an example of a DSA device with good alignment characteristics. In an embodiment, the processes described herein may include capturing an image of a DSA device, similar to the image of FIG. 3. For example, the method may include acquiring one or more top view (aerial) images of the BCP pattern. In an embodiment, each image may include a two-dimensional (2D) array of pixels, each pixel having an intensity value.

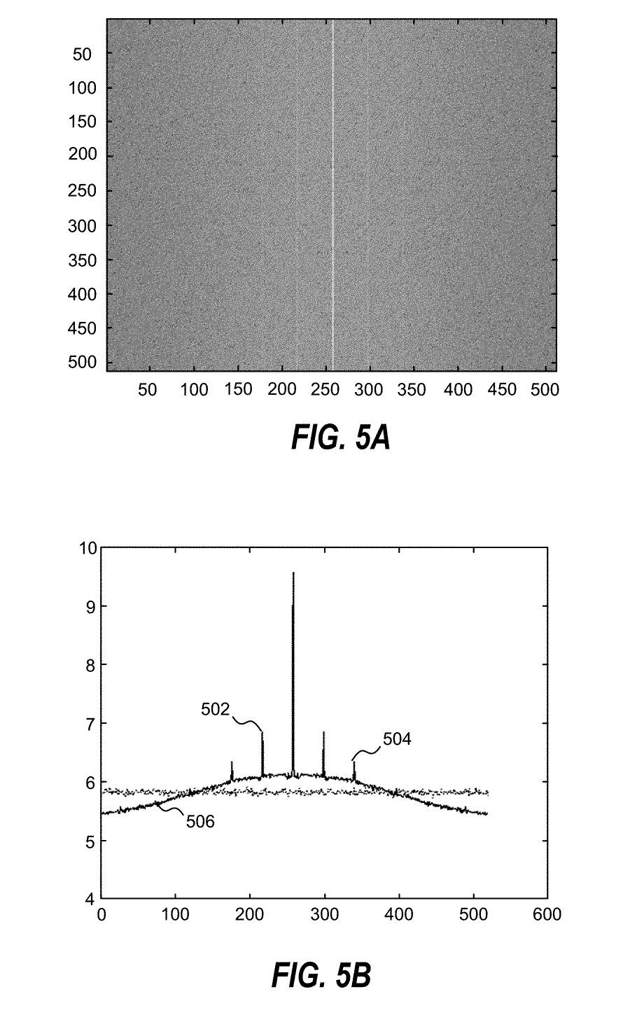

FIG. 4 illustrates an embodiment of an image of a top view of one embodiment of a semiconductor device manufactured by a DSA process, where the resultant BCP pattern has poor alignment. The device shown in the image of FIG. 4 may have one or more defects, including dislocation pair defects, disclination defects, or buried defects. The images shown in FIGS. 3 and 4 may be analyzed according to the embodiments described in FIGS. 5A-8B.

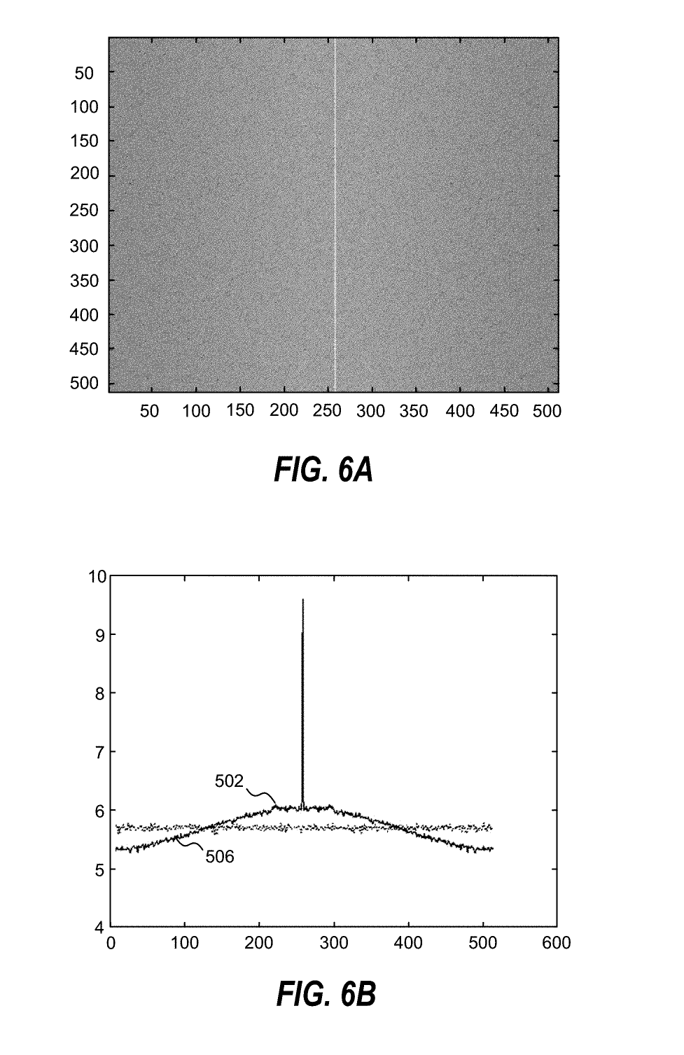

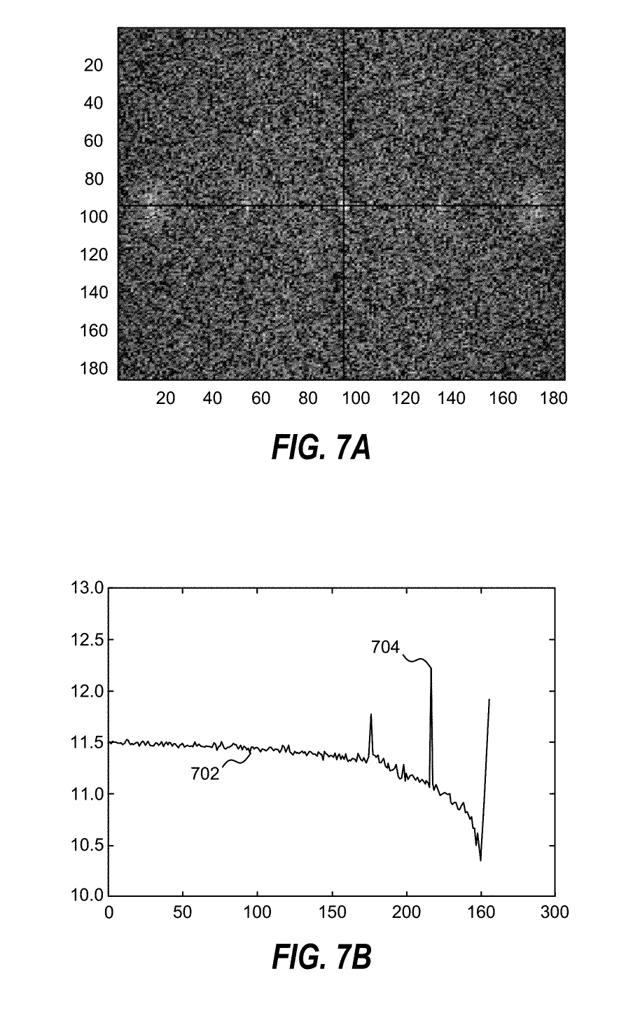

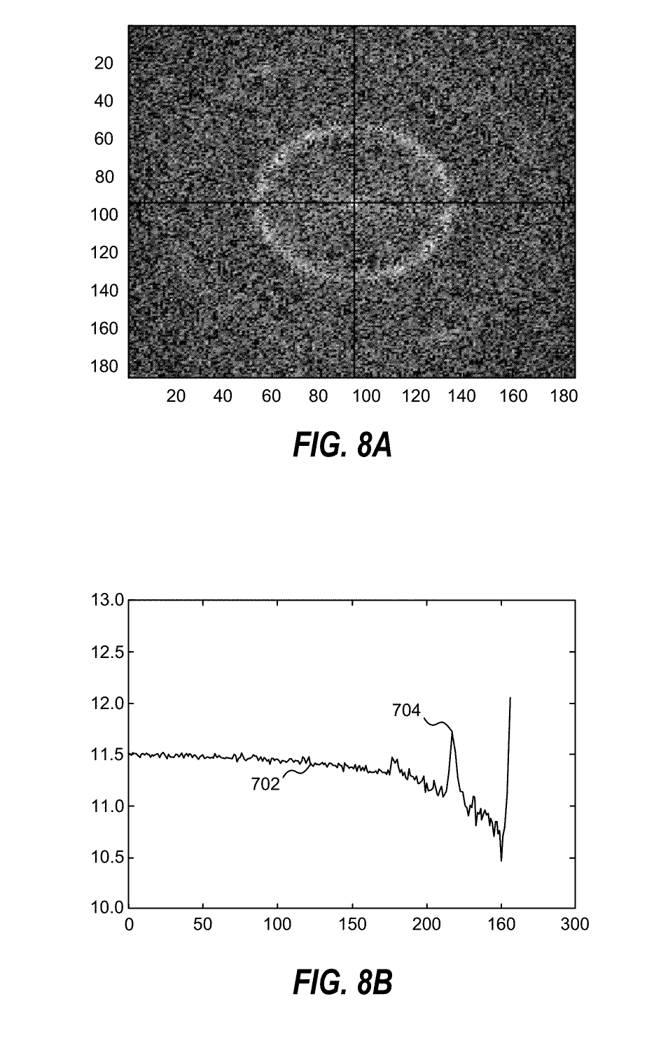

According to some embodiments, the described methods may further include transforming at least one of the one or more aerial images into special frequency domain to form a transform. For example, the transform may include a one-dimensional (1D) transform of a row or column of image pixels, where the power spectrum is measured for each row or column as shown in FIGS. 5A and 6A. Alternatively, the transform may include a 2D transform of a plurality of rows or columns, where the power spectrum is measured for the plurality of rows or columns as shown in FIGS. 7A and 8A. Row or column averages and rotational averages of the 1D and 2D transforms respectively, may be produced and measured at first order peaks, second order peaks, or the like, as shown in FIGS. 5B, 6B, 7B, and 8B. In such embodiments, the transform may be a Fast Fourier Transform (FFT).

FIG. 5A illustrates a one-dimensional power spectrum measurement of each row or column of the image of FIG. 3. Because it may be difficult to assess critical information from a single row or column as shown in FIG. 5A, an average of the power spectrum 506 across rows or columns may be determined and plotted as shown in FIG. 5B. The first order peak 502 or the second order peak 504 may be used to determine alignment of the BCP structure associated with the captured image. As shown in FIG. 5B, both the first order peaks and the second order peaks are relatively high, when compared with the image of FIG. 6B. Thus, the BCP structure captured in the image of FIG. 3 has good alignment characteristics, whereas the BCP structure captured in the image of FIG. 4 has poor alignment characteristics.

FIG. 6A illustrates a one-dimensional power spectrum measurement of each row of the image of FIG. 4. As shown in the graph of FIG. 6B, the BCP structure captured in the image of FIG. 4 has poor alignment characteristics, because the first order peaks and the second order peaks are both so low as to be nearly unidentifiable.

FIG. 7A illustrates a two-dimensional power spectrum measurement of each row of the image of FIG. 3. In an embodiment, the 2D power spectrum of the image may be equivalent to taking a 1D power spectrum of columns or rows of the image, and then taking the 1D power spectrum of that result in the orthogonal direction. FIG. 7B illustrates a rotational average 702 of the 2D power spectrum measurement of the image of FIG. 3. The rotational average may be defined as the rotational average of the points at a given distance r from the center of the 2D power spectrum image.

Rotational averages may be, for example, a 1D plot of 2D FFT intensities binned in a plurality of radial annuli centered at the center of the 2D FFT, and plotted against the radial distance from the center of the 2D FFT, as shown in FIGS. 7B and 8B. In the case of a digital image, the distance r may be an annulus that is approximately one pixel wide. The peak height of the first order peak 704 may be used as a metric for aligned structures. One benefit of the 2D method is that it should work for alignment analysis of arrays aligned in multiple directions. As shown, the image of FIG. 3 has good alignment characteristics, because the first order peak 704 is high relative to the first order peak 704 of FIG. 8B, which shows poor alignment of the BCP structure in the image of FIG. 4. FIG. 8A illustrates the 2D power spectrum measurement of the image of FIG. 4. One of ordinary skill will recognize that the second order peaks may be used as well, or in the alternative. Other metrics may include an area under a peak or a peak width.

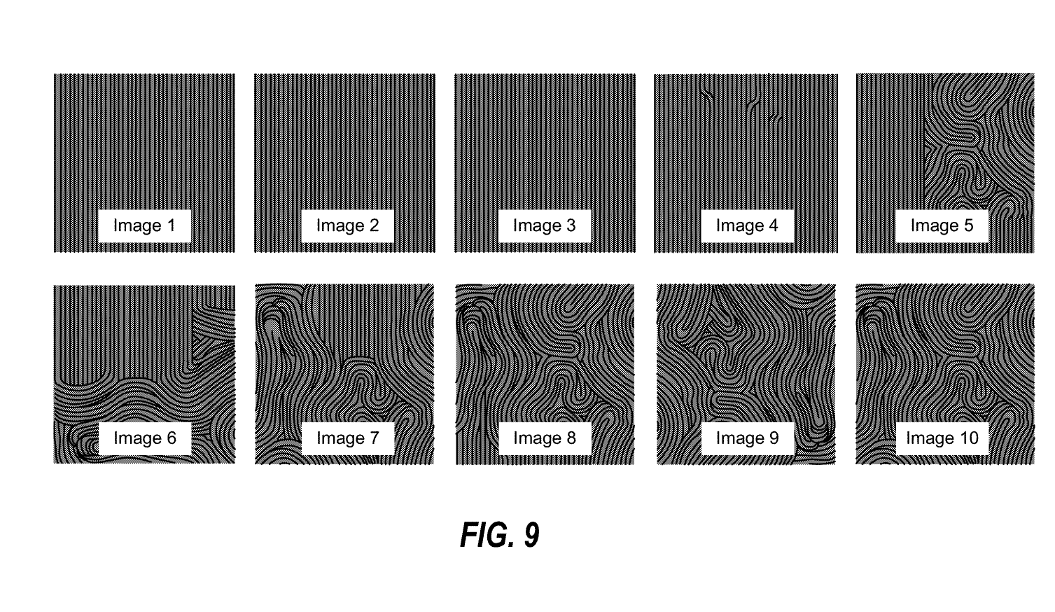

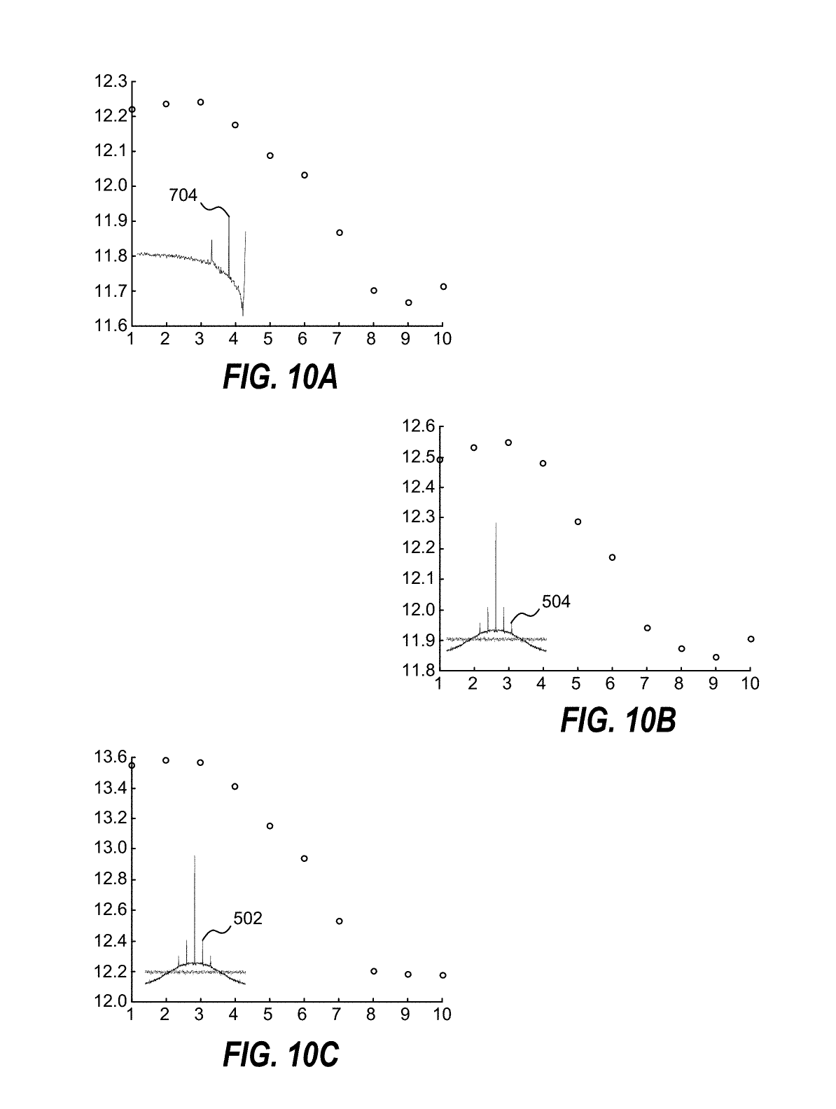

FIG. 9 illustrates a set of images of semiconductor devices manufactured by a DSA process, each being ordered by visual assessment of alignment. This set of images was selected to demonstrate correlation of the measurements with physical alignment of the imaged BCP structures. The image labels correspond to the x-axis of the graphs of FIGS. 10A-10C. As shown, the images range from relatively good alignment (Image 1) to relatively poor alignment (Image 10).

FIG. 10A illustrates measurement values of the first order peak 706 of the rotational average of the 2D power spectrum for each image, where each circle represents the measurement value. Although Images 1-3 appear to be identical visually in terms of alignment, the measured values show that image 3 actually has the best alignment characteristics, which means that the BCP structure shown in image 3 may have slightly better LER, LWR, or CD characteristics than the BCP structure shown in images 1-2 of FIG. 9. Alternatively, the BCP structures of images 1-2 may have some buried defects that are undetectable by visual inspection.

FIG. 10B illustrates a height measurement of the second order peak 504 of the average of the 1D transform for each of the images of FIG. 9. FIG. 10C illustrates a height measurement of the first order peak 502 of the average of the 1D transform for each of the images of FIG. 9. As shown, there is strong correlation between the measurements and visual inspection of the alignment of the BCP structures in the images of FIG. 9. Further, there is strong correlation of all three measurements for each of the images, indicating consistency among measurement protocols. One of ordinary skill will recognize that values other than peak height may be measured, for example, an area underneath the peak, or a width of the peak.

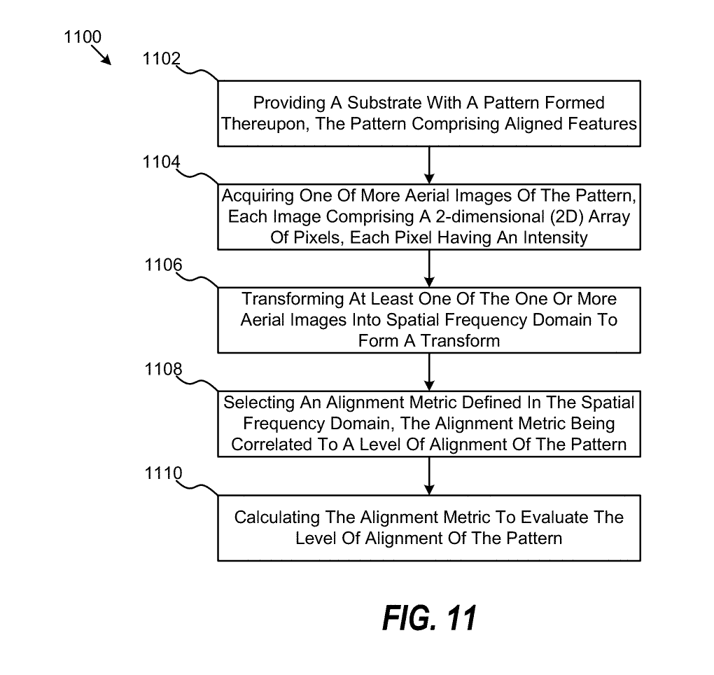

FIG. 11 is a schematic flowchart diagram illustrating one embodiment of a method 1100 for evaluating aligned patterns in DSA semiconductor devices. In an embodiment, the method 1100 includes providing a substrate with a pattern formed thereupon, the pattern comprising aligned features, as shown at block 1102. At block 1104, the method 1100 includes acquiring one of more aerial images of the pattern, each image comprising a 2-dimensional (2D) array of pixels, each pixel having an intensity. The method 1100 may also include transforming at least one of the one or more aerial images into spatial frequency domain to form a transform, as shown at block 1106. Also, the method 1100 may include selecting an alignment metric defined in the spatial frequency domain, the alignment metric being correlated to a level of alignment of the pattern, as shown at block 1108. At block 1110, the method 1100 includes calculating the alignment metric to evaluate the level of alignment of the pattern.

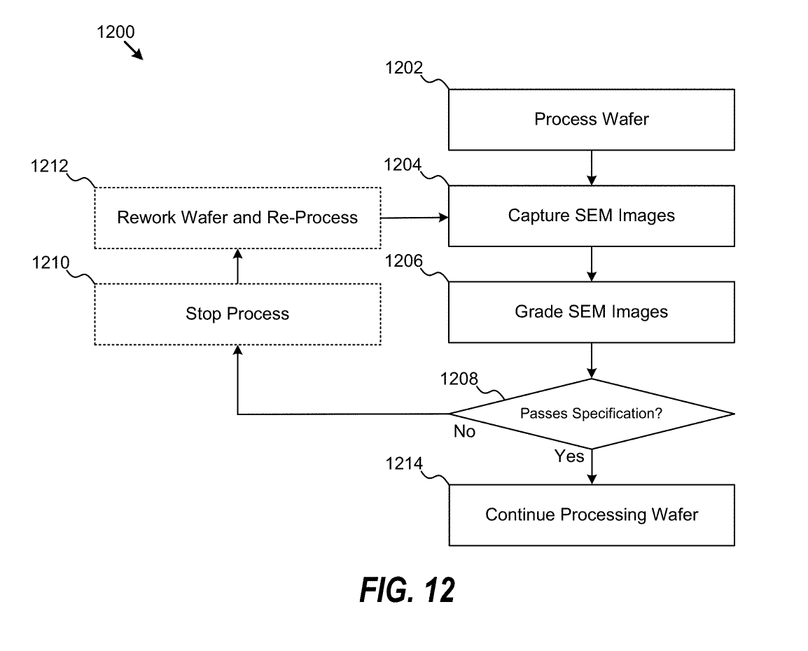

FIG. 12 is a schematic flowchart diagram illustrating one embodiment of a method 1200 for evaluating aligned patterns in DSA semiconductor devices. In an embodiment, the method 1200 may include processing a wafer as shown at block 1202. Processing the wafer may include forming a DSA patterned structure in BCPs over a surface of the wafer as illustrated in FIGS. 1A-1C. In a further embodiment, the method 1200 may include capturing an SEM image of the pattern formed on the wafer. For example, the image may be captured with an image capture device, such as a CDSEM device.

At block 1206, the image may be graded according to one or more of the methods described in FIGS. 5A-10C. For example, a 1D transform may be performed on the image, and the first order peaks 502 of the average of the 1D transform may be measured. Alternatively, the second order peaks 504 may be measured. In another embodiment, a 2D transform may be performed and the first order peaks 704 of the rotational average may be measured. At block 1208, the measurement may be checked against a threshold or alignment specification. If the image passes the specification, then the wafer may continue processing as shown at block 1214. If not, then the process may be stopped and the wafer may be reworked and reprocessed as shown at blocks 1210-1212. Once reworked, the wafer may be reimaged graded, and checked against the threshold iteratively until the wafer passes specification.

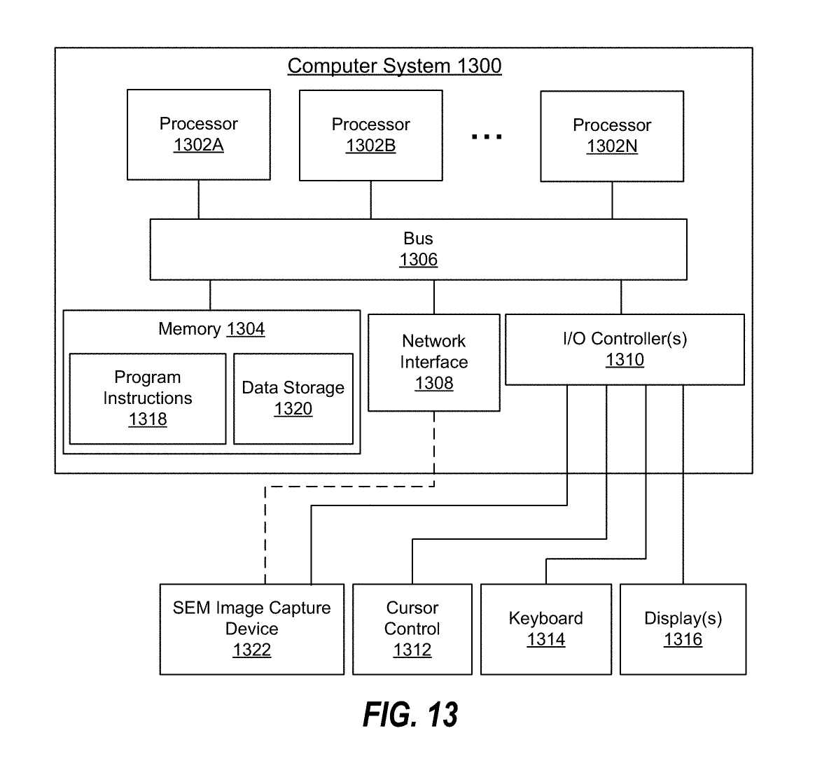

FIG. 13 is a schematic block diagram illustrating one embodiment of a processing system 1300 specially configured for evaluating aligned patterns in DSA semiconductor devices. In various embodiments, the processing system 1300 may be a server, a mainframe processing system, a workstation, a network computer, a desktop computer, a laptop, or the like.

As illustrated, processing system 1300 includes one or more processors 1302A-N coupled to a system memory 1304 via bus 1306. Processing system 1300 further includes network interface 1308 coupled to bus 1306, and input/output (I/O) controller(s) 1310, coupled to devices such as cursor control device 1312, keyboard 1314, and display(s) 1316. In some embodiments, a given entity may be implemented using a single instance of processing system 1300, while in other embodiments multiple such systems, or multiple nodes making up processing system 1300, may be configured to host different portions or instances of embodiments.

In various embodiments, processing system 1300 may be a single-processor system including one processor 1302A, or a multi-processor system including two or more processors 1302A-N (e.g., two, four, eight, or another suitable number). Processor(s) 1302A-N may be any processor capable of executing program instructions. For example, in various embodiments, processor(s) 1302A-N may be general-purpose or embedded processors implementing any of a variety of instruction set architectures (ISAs), such as the x86, POWERPC®, ARM®, SPARC®, or MIPS® ISAs, or any other suitable ISA. In multi-processor systems, each of processor(s) 1302A-N may commonly, but not necessarily, implement the same ISA. Also, in some embodiments, at least one processor(s) 1302A-N may be a graphics processing unit (GPU) or other dedicated graphics-rendering device.

System memory 1304 may be configured to store program instructions and/or data accessible by processor(s) 1302A-N. For example, memory 1304 may be used to store software program and/or database shown in FIGS. 11-12. In various embodiments, system memory 1304 may be implemented using any suitable memory technology, such as static random access memory (SRAM), synchronous dynamic RAM (SDRAM), nonvolatile/Flash-type memory, or any other type of memory. As illustrated, program instructions and data implementing certain operations, such as, for example, those described above, may be stored within system memory 1304 as program instructions 1318 and data storage 1320, respectively. In other embodiments, program instructions and/or data may be received, sent or stored upon different types of computer-accessible media or on similar media separate from system memory 1304 or processing system 1300. Generally speaking, a computer-accessible medium may include any tangible, non-transitory storage media or memory media such as electronic, magnetic, or optical media—e.g., disk or CD/DVD-ROM coupled to processing system 1300 via bus 1306, or non-volatile memory storage (e.g., “flash” memory)

In an embodiment, bus 1306 may be configured to coordinate I/O traffic between processor 1302, system memory 1304, and any peripheral devices including network interface 1308 or other peripheral interfaces, connected via I/O controller(s) 1310. In some embodiments, bus 1306 may perform any necessary protocol, timing or other data transformations to convert data signals from one component (e.g., system memory 1304) into a format suitable for use by another component (e.g., processor(s) 1302A-N). In some embodiments, bus 1306 may include support for devices attached through various types of peripheral buses, such as a variant of the Peripheral Component Interconnect (PCI) bus standard or the Universal Serial Bus (USB) standard, for example. In some embodiments, the operations of bus 1306 may be split into two or more separate components, such as a north bridge and a south bridge, for example. In addition, in some embodiments some or all of the operations of bus 1306, such as an interface to system memory 1304, may be incorporated directly into processor(s) 1302A-N.

Network interface 1308 may be configured to allow data to be exchanged between processing system 1300 and other devices, such as other processing systems attached to data processor 102, for example. In various embodiments, network interface 1308 may support communication via wired or wireless general data networks, such as any suitable type of Ethernet network, for example; via telecommunications/telephony networks such as analog voice networks or digital fiber communications networks; via storage area networks such as Fiber Channel SANs, or via any other suitable type of network and/or protocol.

I/O controller(s) 1310 may, in some embodiments, enable connection to one or more display terminals, keyboards, keypads, touch screens, scanning devices, voice or optical recognition devices, or any other devices suitable for entering or retrieving data by one or more processing system 1300. Multiple input/output devices may be present in processing system 1300 or may be distributed on various nodes of processing system 1300. In some embodiments, similar I/O devices may be separate from processing system 1300 and may interact with processing system 1300 through a wired or wireless connection, such as over network interface 1308.

The terms “tangible” and “non-transitory,” as used herein, are intended to describe a computer-readable storage medium (or “memory”) excluding propagating electromagnetic signals; but are not intended to otherwise limit the type of physical computer-readable storage device that is encompassed by the phrase computer-readable medium or memory. For instance, the terms “non-transitory computer readable medium” or “tangible memory” are intended to encompass types of storage devices that do not necessarily store information permanently, including, for example, RAM. Program instructions and data stored on a tangible computer-accessible storage medium in non-transitory form may afterwards be transmitted by transmission media or signals such as electrical, electromagnetic, or digital signals, which may be conveyed via a communication medium such as a network and/or a wireless link.

As shown in FIG. 13, memory 1304 may include program instructions 1318, configured to implement certain embodiments described herein, and data storage 1320, comprising various data accessible by program instructions 1318. In an embodiment, program instructions 1318 may include software elements of embodiments illustrated in FIGS. 11-12. For example, program instructions 1318 may be implemented in various embodiments using any desired programming language, scripting language, or combination of programming languages and/or scripting languages. Data storage 1320 may include data that may be used in these embodiments such as, for example, image files and transform data. In other embodiments, other or different software elements and data may be included.

A person of ordinary skill in the art will appreciate that processing system 1300 is merely illustrative and is not intended to limit the scope of the disclosure described herein. In particular, the processing system and devices may include any combination of hardware or software that can perform the indicated operations. In addition, the operations performed by the illustrated components may, in some embodiments, be performed by fewer components or distributed across additional components. Similarly, in other embodiments, the operations of some of the illustrated components may not be performed and/or other additional operations may be available. Accordingly, systems and methods described herein may be implemented or executed with other processing system configurations.

In addition, the system may be coupled to an image capture device 1322 configured to capture images of the wafer, such as the images depicted in FIG. 3-4, or 9. In an embodiment, the image capture device 1322 may be an SEM image capture device, such as a CDSEM. The images captured may be stored in the memory 1304, or in a remotely accessible data storage device. One or more of the processors 1302A-N may be configured, according to the program instructions 1318, to perform the frequency domain transform of the captured image. In an embodiment, the transform may be a 1D Fast Fourier Transform (FFT) of intensities of a line of pixels in the image captured by the image capture device 1322. Further, the processor(s) 1302A-N may calculate an average of a plurality of 1D FFTs for a plurality of lines of pixels. Alternatively, the processor(s) 1302A-N may perform a 2D FFT on the image captured by the image capture device 1322, and compute a rotational average of radial peaks centered at the center of the 2D FFT.

Additional advantages and modifications will readily appear to those skilled in the art. The invention in its broader aspects is therefore not limited to the specific details, representative apparatus and method, and illustrative examples shown and described. Accordingly, departures may be made from such details without departing from the scope of the general inventive concept.

We claim:

1. A method of inspecting a pattern, comprising:
providing a substrate with a pattern formed thereupon, the pattern comprising aligned features;
acquiring one of more aerial images of the pattern, each image comprising a 2-dimensional (2D) array of pixels, each pixel having an intensity;
transforming at least one of the one or more aerial images into spatial frequency domain to form a transform;
selecting an alignment metric defined in the spatial frequency domain, the alignment metric being correlated to a level of alignment of the pattern; and
calculating the alignment metric to evaluate the level of alignment of the pattern.

2. The method of claim 1, wherein the pattern comprises a plurality of parallel lines.

3. The method of claim 1, wherein the pattern comprises a block copolymer (BCP) pattern.

4. The method of claim 1, wherein the pattern is undeveloped.

5. The method of claim 1, wherein the transform comprises a one-dimensional (1D) transform of intensities of a line of pixels.

6. The method of claim 1, wherein the transform comprises a 1D Fast Fourier transform (FFT) of intensities of a line of pixels.

7. The method of claim 1, wherein the transform comprises an average of a plurality of 1D FFTs of a plurality of lines of pixels.

8. The method of claim 1, wherein the alignment metric comprises a property of a peak of the transform.

9. The method of claim 8, wherein the property of the peak of the transform is a peak intensity, an area underneath the peak, or a width of the peak.

10. The method of claim 8, wherein the peak is a 1st order peak or a 2nd order peak of the transform.

11. The method of claim 1, wherein the transform comprises a 2D transform of intensities of pixels.

12. The method of claim 1, wherein the transform comprises a 2D FFT of intensities of pixels, the 2D FFT comprising a plurality of radial peaks centered at the center of the 2D FFT.

13. The method of claim 12, wherein the alignment metric comprises a property of a radial peak of the transform.

14. The method of claim 12, wherein the property of the radial peak of the transform is a peak intensity, an area underneath the peak, or a width of the peak.

15. The method of claim 12, wherein the radial peak is a 1st order radial peak or a 2nd order radial peak of the transform.

16. The method of claim 1, wherein the transform comprises a 1D plot of 2D FFT intensities binned in a plurality of radial annuli centered at the center of the 2D FFT, and plotted against radial distance from the center of the 2D FFT.

17. The method of claim 16, wherein the alignment metric comprises a property of a peak of the transform.

18. The method of claim 16, wherein the property of the peak of the transform is a peak intensity, an area underneath the peak, or a width of the peak.

19. The method of claim 16, wherein the peak is a 1st order peak or a 2nd order peak of the transform.

20. The method of claim 1, further comprising:
comparing the calculated alignment metric to a predetermined threshold alignment metric value to determine the level of alignment of the pattern; and
directing the substrate to a pattern rework process flow if the level of alignment of the pattern is unsatisfactory.
